(19) United States
(12) Patent Application Publication
(10) Pub. No.: US 2026/0182254 A1
(43) Pub. Date: Jun. 25, 2026

(54) SUPERCONDUCTING DEVICE AND METHOD FOR REMOVING CONNECTOR UNIT

(71) Applicant: NEC Corporation, Tokyo (JP)

(72) Inventors: Suguru Watanabe, Tokyo (JP); Kunihiko Ishihara, Tokyo (JP); Tomohiro Nishiyama, Tokyo (JP)

(73) Assignee: NEC Corporation, Tokyo (JP)

(21) Appl. No.: 19/370,910

(22) Filed: Oct. 28, 2025

(30) Foreign Application Priority Data
Dec. 20, 2024 (JP) 2024-225821

(51) Int. Cl. H10N 60/81

(52) U.S. Cl. CPC H10N 60/81

(57) ABSTRACT

A superconducting device includes a chip that has a superconducting circuit, an interposer on which the chip is mounted, a board electrically connected to the interposer, a cooling unit to which the board is fixed, a first screw that fixes the board to the cooling unit and has a first head portion in which a first screw hole is formed, and a connector unit fixable to the first screw hole, in which the connector unit has a second screw hole positioned in an extension direction of the first screw hole with respect to the first screw hole.

This application is based upon and claims the benefit of priority from Japanese patent application No. 2024- 225821, filed on December 20, 2024, the disclosure of which is incorporated herein in its entirety by reference.

### TECHNICAL FIELD

The present disclosure relates to a superconducting device and a method for removing a connector unit.

### BACKGROUND ART

A superconducting device including a qubit circuit has been known.

For example, PTL 1 (JP 05-299859 A) discloses “a mounting structure of a substrate unit including the substrate unit in which a printed circuit board is held on a frame including a screw rod, and a back panel unit in which a back panel on which a plurality of the substrate units is vertically mounted is held on the frame”. The frame of the back panel unit is provided with a flange that includes a guide hole that guides the screw rod of the substrate unit to guide a connector of the printed circuit board to a plug-in position, and a screw hole into which a set screw that pushes the frame of the substrate unit in a disconnection direction is screwed when the substrate unit is removed, and that abuts on the frame of the substrate unit and regulates a plug-in depth of the printed circuit board. The substrate unit is fastened to the flange of the back panel unit by a nut screwed into the screw rod.

In the mounting structure of the substrate unit disclosed in PTL 1, the guide hole is provided in the flange for mounting the substrate unit. In the mounting structure of the substrate unit, the screw hole is also provided in the flange for removing the substrate unit. The flange is provided with the guide hole and the screw hole at individual positions. An operator attaches and detaches the connector of the printed circuit board by selectively using the guide hole and the screw hole for each application.

Meanwhile, in a quantum computer using superconductivity, a superconducting device including a chip having a superconducting circuit is mounted in a limited space under a cryogenic temperature. Therefore, space saving of the superconducting device is required. When the connector is attached to and detached from the superconducting device in accordance with the mounting structure of the substrate unit disclosed in PTL 1, a space for providing the two types of holes is required for attaching and detaching the connector. As the space is required, the superconducting device may be enlarged.

An object of the present disclosure is to provide a superconducting device and a method for removing a connector unit for solving the above-described problem.

### SUMMARY

A superconducting device of the present disclosure includes a chip that has a superconducting circuit, an interposer on which the chip is mounted, a board electrically connected to the interposer, a cooling unit to which the board is fixed, a first screw that fixes the board to the cooling unit and has a first head portion in which a first screw hole is formed, and a connector unit fixable to the first screw hole, in which the connector unit has a second screw hole positioned in an extension direction of the first screw hole with respect to the first screw hole.

A method for removing a connector unit in a superconducting device comprising an interposer on which a chip having a superconducting circuit is mounted, a first screw that fixes a board electrically connected to the interposer to a cooling unit and has a first head portion in which a first screw hole is formed, a connector unit fixable to the first screw hole and having a second screw hole positioned in an extension direction of the first screw hole, and a second screw including a second shaft portion engageable with the second screw hole, the method includes engaging the second shaft portion with the second screw hole, and pressing the first head portion with a screw tip of the second screw.

According to a superconducting device and a method for removing a connector unit according to the present disclosure, space saving of the superconducting device is easily achieved.

### BRIEF DESCRIPTION OF THE DRAWINGS

FIG. 1 is a plan view illustrating an example of a configuration of a superconducting device according to the present disclosure;

FIG. 2 is a cross-sectional view taken along a line F2-F2 illustrated in FIG. 1;

FIG. 3 is a cross-sectional view taken along a line F3-F3 illustrated in FIG. 1;

FIG. 4 is a plan view illustrating an example of the configuration of the superconducting device according to the present disclosure;

FIG. 5 is a cross-sectional view taken along the line F3-F3 illustrated in FIG. 4;

FIG. 6 is a cross-sectional view illustrating an example of a second screw in the present disclosure;

FIG. 7 is a cross-sectional view illustrating an example of the second screw in the present disclosure;

FIG. 8A is a view illustrating removal of a connector in the superconducting device according to the present disclosure;

FIG. 8B is a view illustrating removal of a connector in the superconducting device according to the present disclosure;

FIG. 9 is a flowchart illustrating an example of processing of a method for removing a connector unit according to the present disclosure;

FIG. 10A is a view illustrating removal of the connector in the superconducting device according to modifications;

FIG. 10B is a view illustrating removal of the connector in the superconducting device according to modifications;

FIG. 11 is a cross-sectional view illustrating an example of a configuration of a superconducting device according to the present disclosure;

FIG. 12 is a cross-sectional view taken along a line F12-F12 illustrated in FIG. 11; and

FIG. 13 is a flowchart II illustrating an example of processing of a method for removing a connector unit according to the present disclosure.

### EXAMPLE EMBODIMENT

Hereinafter, examples of example embodiments according to the present disclosure will be described with reference to the drawings. The drawings and specific configurations used in the example embodiments should not be used for interpretation of the disclosure. In all the drawings, the same or related components are denoted by the same reference numerals, and the common description will be omitted.

In the present disclosure, the drawings are associated with one or more example embodiments.

### First Example Embodiment

Hereinafter, one example embodiment according to the present disclosure will be described with reference to the drawings.

Hereinafter, an example of a configuration of a superconducting device in the present disclosure will be described with reference to the drawings.

In the following disclosure, a Z direction is one direction in which a front surface 21s1 of a base material 21 included in an interposer 2 faces. One of the Z direction is a +Z direction, and the other of the Z direction is a -Z direction. An X direction is one direction intersecting the Z direction in a plane along the front surface 21s1. One of the X direction is a +X direction, and the other of the X direction is a -X direction. A Y direction is one direction intersecting the Z direction and the X direction. One of the Y direction is a +Y direction, and the other of the Y direction is a -Y direction.

Hereinafter, in a case where the X direction and the Y direction are not distinguished from each other, the X direction and the Y direction may be referred to as a “horizontal direction”. Hereinafter, the Z direction may be referred to as a “vertical direction”.

### Configuration of Superconducting Device

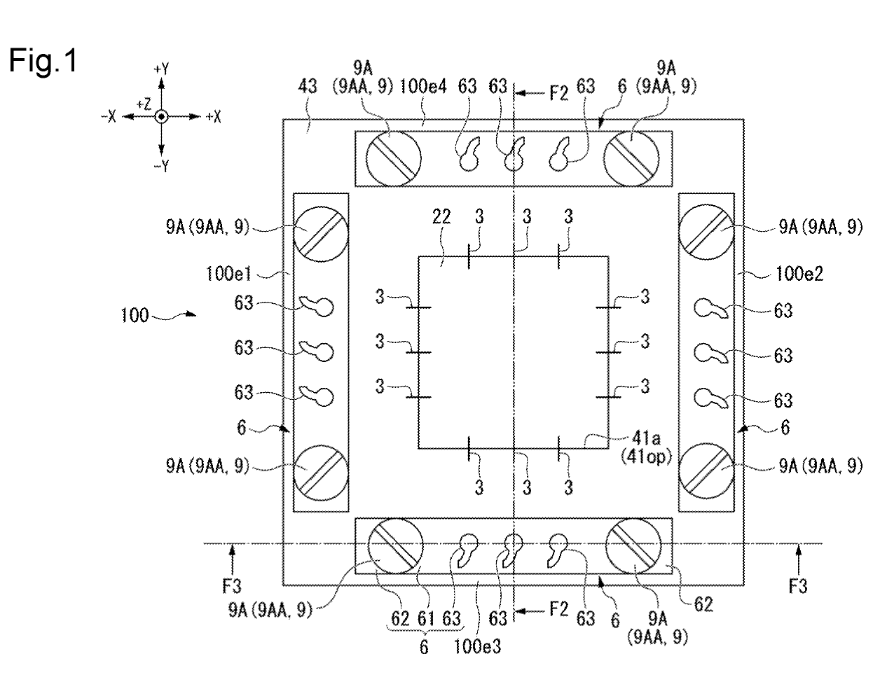

As illustrated in FIGS. 1 to 3, a superconducting device 100 includes a quantum chip 1, the interposer 2, a plurality of bonding wires 3, a board 4, a cooling unit 5, at least one or more connector units 6, a first screw 8, and a second screw 9. In the present disclosure, the superconducting device 100 includes the four connector units 6.

Arrangement of the connector units 6 in the superconducting device 100 is not particularly limited. For example, as illustrated in FIG. 1, the superconducting device 100 has a first end 100e1, a second end 100e2, a third end 100e3, and a fourth end 100e4. The first end 100e1 and the second end 100e2 are a pair of ends separated in the X direction. The third end 100e3 and the fourth end 100e4 are a pair of ends separated in the Y direction. At this time, among the four connector units 6 in the present disclosure, one is positioned at the first end 100e1, one is positioned at the second end 100e2, one is positioned at the third end 100e3, and one is positioned at the fourth end 100e4.

This superconducting device 100 has a basic configuration in which the quantum chip 1 is connected to the board 4 via the interposer 2, and the bonding wires 3 are used for connecting the interposer 2 and the board 4. The cooling unit 5 stores the quantum chip 1, and maintains a cryogenic temperature that enables achievement of a quantum state.

A feature of the superconducting device 100 in the present disclosure is that a removal structure of the connector unit 6 in which a first screw hole and a second screw hole positioned in an extension direction of the screw holes are selectively used. Therefore, the connection between the interposer 2 and the board 4 is not particularly limited.

### Configuration of Quantum Chip

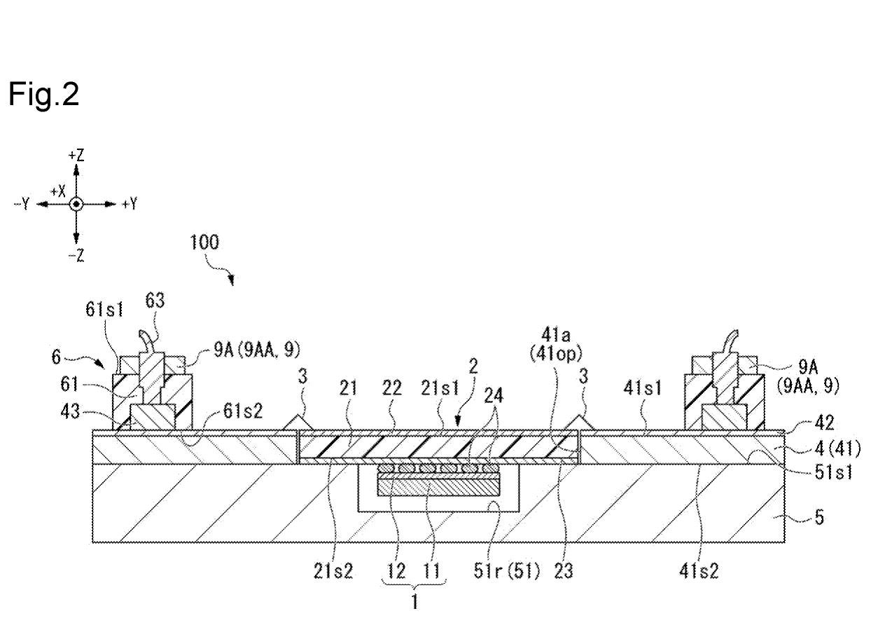

As illustrated in FIG. 2, the quantum chip 1 includes a base material 11 and a connection unit 12. The connection unit 12 constitutes a qubit circuit (superconducting circuit) on the base material 11. The connection unit 12 does not necessarily have to include a conductor wiring layer that forms a circuit pattern as long as it is a conductor that can be connected to a circuit element in the quantum chip 1.

The wiring layer (connection unit 12) of the quantum chip 1 is mounted over the interposer 2 via bumps 24. Therefore, the quantum chip 1 is flip-chip mounted over the interposer 2. In the present disclosure, the quantum chip 1 is mounted on a back surface 21s2 described later.

The connection unit 12 preferably contains a superconducting material.

More specifically, the base material 11 contains a material that is less deformed in a superconducting environment, such as silicon (Si), gallium arsenide (GaAs), sapphire, or glass. The connection unit 12 is niobium nitrides such as niobium (Nb) or niobium nitride, aluminum (Al), indium (In), lead (Pb), tin (Sn), rhenium (Re), palladium (Pd), titanium (Ti), titanium nitrides, tantalum (Ta), tantalum nitrides, or an alloy having superconductivity and containing at least one of these.

### Configuration of Interposer

As illustrated in FIG. 2, the interposer 2 includes the base material 21, a first wiring layer 22, a second wiring layer 23, and the at least one or more bumps 24. The base material 21 has the front surface 21s1 and the back surface 21s2. The front surface 21s1 faces the +Z direction. The back surface 21s2 faces the -Z direction. The first wiring layer 22 is provided on the front surface 21s1 of the base material 21. The second wiring layer 23 is provided on the back surface 21s2.

The interposer 2 is housed in an opening 41op. In the housed interposer 2, the back surface 21s2 of the base material 21 covers a recess 51r. A part of the back surface 21s2 of the base material 21 is in contact with the cooling unit 5. In this case, the interposer 2 may be disposed with a space interposed between the interposer 2 and an inner peripheral surface 4a of the opening 41op of the board 4. With such a configuration, it is possible to minimize stress and strain due to a difference in shrinkage between the interposer 2 and the board 4, caused by a temperature change to a cryogenic temperature. The interposer 2 may be disposed in such a way as to abut on a part of the inner peripheral surface 4a of the opening 41op of the board 4. When the interposer 2 abuts, a part of movement of the interposer 2 is restrained in the horizontal direction.

Similarly to the quantum chip 1, the base material 21 contains a material that is less deformed in a superconducting environment, such as silicon (Si), gallium arsenide (GaAs), sapphire, or glass.

The first wiring layer 22 and the second wiring layer 23 contain niobium nitrides such as niobium (Nb) or niobium nitride, aluminum (Al), indium (In), lead (Pb), tin (Sn), rhenium (Re), palladium (Pd), titanium (Ti), titanium nitrides, tantalum (Ta), tantalum nitrides, or an alloy having superconductivity and containing at least one of these.

For example, in the present disclosure, the interposer 2 and the board 4 are bonded at the front surface 21s1. The bonding is performed by using the bonding wires 3. In the present disclosure, the quantum chip is mounted on the back surface 21s2. As a result, the number of bonding wires 3 on the front surface 21s1 is easily increased.

The interposer 2 may include a through via. The through via is used to acquire a ground potential from the cooling unit 5.

The bump 24 may contain the same superconducting material as the connection unit 12 or may contain a superconducting material different from the connection unit 12. In a case where the bump 24 includes a plurality of metal layers, at least one layer preferably contains a superconducting material.

In the present example embodiment, since a part of the back surface 21s2 comes into contact with the cooling unit 5, the quantum chip 1 is housed in a space formed by the recess 51r of a main body 51 of the cooling unit 5 and the interposer 2.

### Configuration of Bonding Wire

The bonding wires 3 are used to extract information from the quantum chip 1 mounted on the interposer 2.

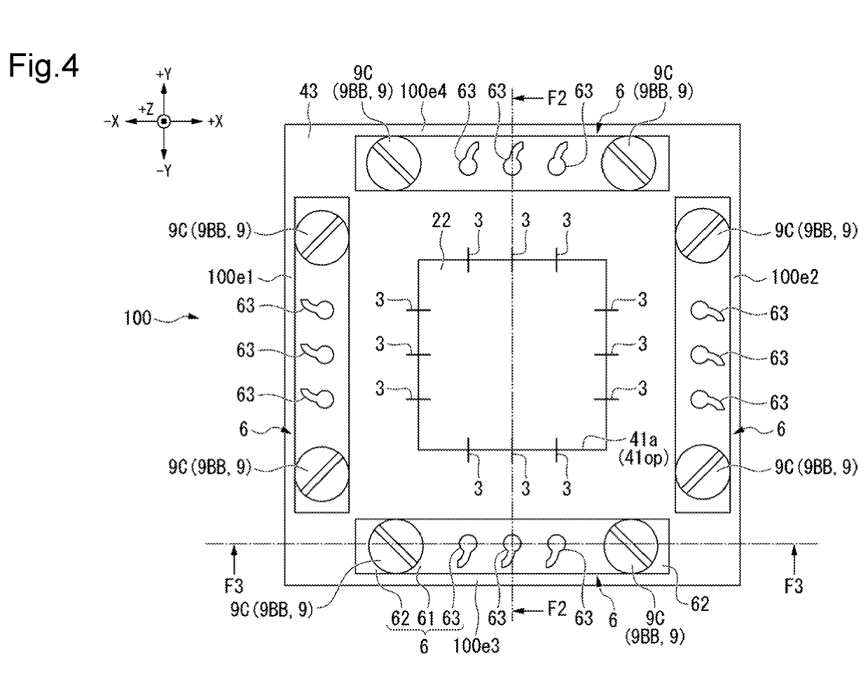

As illustrated in FIG. 2, the bonding wires 3 electrically connect the first wiring layer 22 of the interposer 2 and a third wiring layer 42 of the board 4. Signal information of the quantum chip 1 is transmitted to the interposer 2, the bonding wires 3, a first connector 43, and a second connector 63 in this order. In FIGS. 1 and 4, the bonding wires 3 are simplified.

The bonding wire 3 contains niobium nitrides such as niobium (Nb) and niobium nitride, aluminum (Al), palladium (Pd), titanium (Ti), titanium nitride, gold (Au), platinum (Pt), or an alloy containing at least one of these.

### Configuration of Board

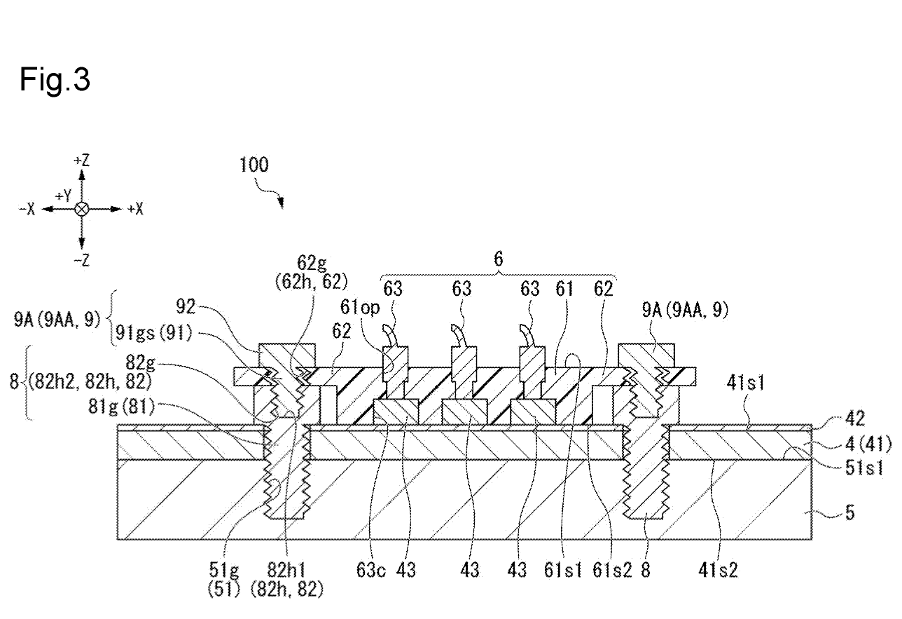

As illustrated in FIGS. 2 and 3, the board 4 includes a base material 41, the third wiring layer 42, and the at least one or more first connectors 43. In the present disclosure, the board 4 includes the 12 first connectors 43. The first connector 43 is a connection unit that can be electrically connected to the second connector 63 included in the connector unit 6. The first connector 43 includes a coaxial connector, a flat cable connector, and other connectors that can be inserted and removed in one direction. The first connector 43 may have a male connector shape or a female connector shape.

The base material 41 has the opening 41op. The opening 41op exposes the recess 51r in a state where there is no interposer 2. A part of the cooling unit 5 exposed by the opening 41op is a peripheral portion of an upper edge of the recess 51r.

For example, in the present example embodiment, the base material 41 has a plate shape. The base material 41 has a front surface 41s1 and a back surface 41s2. The front surface 41s1 faces the +Z direction. The back surface 41s2 is a surface facing the -Z direction. The third wiring layer 42 is provided on the front surface 41s1 of the base material 41.

The cooling unit 5 abuts on the back surface 41s2. The third wiring layer 42 is provided with the first connectors 43.

The base material 41 has, on the front surface 41s1, a bearing surface for supporting the first screw 8. The bearing surface is provided with a through hole through which the first screw 8 can be inserted. As a result, the board 4 is fixed to the cooling unit 5 by the first screw 8.

The base material 41 may contain, as a material, epoxy, acrylic, urethane, polyimide, phenol, a liquid crystal polymer, or the like, and may further contain silica, an organic resin, a ceramic filler, or glass fiber in addition to such a material. The base material 41 may contain a solidified ceramic powder.

The third wiring layer 42 provided on the front surface 41s1 contains, for example, a material such as copper (Cu) or aluminum (Al), and is formed in a predetermined circuit pattern by means such as sputtering, vapor deposition, electroless plating, or electrolytic plating. As a specific method for forming a layer containing a conductive material into the predetermined circuit pattern, a subtractive method using a resist applied to the front surface as a mask, an additive method using plating, a semi-additive method, a lift-off method in which the applied resist is removed to form a pattern, or the like can be applied.

### Configuration of Cooling Unit

As illustrated in FIGS. 2 and 3, the board 4 is fixed to the cooling unit 5.

The cooling unit 5 has a cooling function. Examples of the cooling unit 5 include a stage. The stage is a so-called cold stage including a cryogenic refrigerator (not illustrated) of about milliKelvin [mK] capable of achieving a superconducting state in the materials constituting the quantum chip 1 and the interposer 2.

The cooling unit 5 includes the main body 51. The main body 51 has a front surface 51s1. The front surface 51s1 faces the +Z direction. The interposer 2 and the board 4 abut on the front surface 51s1.

When the interposer 2 abuts on the front surface 51s1, the back surface 21s2 of the interposer 2 covers the recess 51r. The main body 51 has a hole through which the first screw 8 can be inserted on a contact surface with the board 4.

The main body 51 has the recess 51r recessed in a direction (for example, the -Z direction) opposite to a direction facing the interposer 2. The recess 51r has a shape related to a planar shape of the quantum chip 1 on an XY plane. The recess 51r houses the quantum chip 1. In the present disclosure, a gap is formed between the quantum chip 1 and the recess 51r.

The main body 51 desirably contains, for example, a metal such as copper (Cu) or a copper alloy.

For example, in a case where niobium (Nb) is contained as the superconducting material of the quantum chip 1, a superconducting phenomenon at a cryogenic temperature of equal to or less than 9.2 Kelvin [K] is used, and in a case where aluminum (Al) is contained, a superconducting phenomenon at a cryogenic temperature of equal to or less 1.2 Kelvin [K] is used, and therefore, a cooling capacity capable of achieving the cryogenic temperatures exemplified above is required for the cooling unit 5.

When at least a part of the interposer 2 is in contact with the cooling unit 5, the interposer 2 functions as a heat transfer path, and the qubit circuit included in the quantum chip 1 is cooled to a cryogenic temperature.

In this manner, the superconducting phenomenon can be used.

The ground potential of the interposer 2 may be acquired from the cooling unit 5. For example, the ground potential of the interposer 2 is acquired via the through via of the interposer 2 that abuts on the cooling unit 5. In this case, the board 4 acquires the ground potential by bonding to the interposer 2 via the bonding wires 3.

### Configuration of Connector Unit

As illustrated in FIGS. 2 and 3, the connector unit 6 is used to exchange input and output between an external device and the quantum chip 1. For example, the external device inputs and outputs a power supply, a signal, and the like to and from the quantum chip 1 via electrical connection between the second connector 63 and the first connector 43 described later.

The connector unit 6 includes a main body 61, a pair of attachment portions 62, and the at least one or more second connectors 63. In the present disclosure, the connector unit 6 includes the three second connectors 63. The connector unit 6 can fix the attachment portions 62 to fourth grooves 82g. The second connector 63 has a connector shape that can be fitted to the above-described first connector 43. The second connector 63 has the connector shape that can be fitted to the first connector 43.

The main body 61 holds the plurality of second connectors 63. The main body 61 is an example of a “first holding unit”.

The main body 61 has a front surface 61s1 and a back surface 61s2. The front surface 61s1 is a surface positioned on a side opposite to the back surface 61s2. The front surface 61s1 in the present example embodiment faces the +Z direction. The back surface 61s2 faces the first wiring layer 22. The back surface 61s2 in the present example embodiment faces the -Z direction. Each of the second connectors 63 is inserted from the front surface 61s1. The first wiring layer 22 can be in contact with the back surface 61s2.

A shape of the main body 61 is not particularly limited. For example, in the present example embodiment, the main body 61 extends along the horizontal direction. A cross section in the vertical direction of the main body 61 has a rectangular cross-sectional shape.

The main body 61 includes a plurality of openings 61op. Each opening 61op opens in a first direction (for example, the Z direction). The openings 61op are through holes. A part of an inner peripheral surface of the opening 61op is along an outer shape of the second connector 63. The second connector 63 is held at a predetermined position by the inner peripheral surface. At least a part of the second connector 63 is housed in the opening 61op.

The main body 61 may include a counterbore 63c. The counterbore 63c is formed around an opening portion of the opening 61op on the back surface 61s2. A part of an inner peripheral surface of the counterbore 63c is along the outer shape of the second connector 63. In the present example embodiment, the main body 61 includes the plurality of openings 61op and counterbores 63c. In a third modification described later, the main body 61 does not have to include the counterbores 63c. This is because an opening 71op in the third modification has a configuration similar to that of the counterbore 63c.

The main body 61 preferably contains an insulating material. The main body 61 contains the insulating material at a portion in contact with the second connector 63 and the first wiring layer 22. The main body 61 also preferably contains a non-magnetic material. More preferably, the main body 61 may be constituted of a non-magnetic material.

The main body 61 may contain quartz or plastic such as engineering plastic. The main body 61 may also contain a composite material including aluminum oxide (also referred to as Al₂O₃ or alumina), a mica-based machinable ceramic, aluminum nitride (AlN), zirconia (ZrO₂), a macol-based machinable ceramic, glass, a resin, and a silica filler. The main body 61 may contain a superconducting material as long as insulation is secured between the main body 61 and the second connector 63 and between the main body 61 and the first wiring layer 22. The superconducting material functions as magnetic shielding during cooling. Therefore, electromagnetic noise is less likely to be applied to the qubit circuit.

The attachment portions 62 are provided at ends of the main body 61. One attachment portion 62 of the pair of attachment portions 62 extends from one end of the main body 61 along the horizontal direction. The other attachment portion 62 extends from the other end of the main body 61 along the horizontal direction. The attachment portion 62 has a bearing surface that supports the second screw 9. A second head portion 92 of the second screw 9 can come into contact with the bearing surface.

The attachment portion 62 has a hole (hereinafter, also referred to as the “second screw hole”) through which the second screw 9 can be inserted. The second screw hole is an engagement hole 62h opened in the Z direction. The engagement hole 62h is a through hole. An inner peripheral surface of the engagement hole 62h has a second groove 62g.

The second screw hole is positioned in an extension direction of the first screw hole with respect to the first screw hole described later. In the present disclosure, the extension direction is the Z direction.

An axis of the second groove 62g and an axis of the fourth groove 82g may or may not match. When the axis of the second groove 62g and the axis of the fourth groove 82g do not match, it is preferable to use a “third type second screw 9C” described later.

The attachment portion 62 may contain the same material as that of the main body 61 or may contain a material different from that of the main body 61.

### Configuration of First Screw

As illustrated in FIGS. 1 to 5, the first screw 8 fixes the board 4 to the cooling unit 5.

The first screw 8 has a hole (hereinafter, also referred to as the “first screw hole”) through which the second screw 9 can be inserted. The first screw hole is an engagement hole 82h opened in the Z direction. The engagement hole 82h has a bottom surface 82h1 and a side peripheral surface 82h2. The bottom surface 82h1 is a surface facing the +Z direction.

The bottom surface 82h1 extends in the horizontal direction. The side peripheral surface 82h2 is a surface extending from the bottom surface 82h1 along the +Z direction. The side peripheral surface 82h2 of the engagement hole 82h surrounds the bottom surface 82h1. The side peripheral surface 82h2 has the fourth groove 82g.

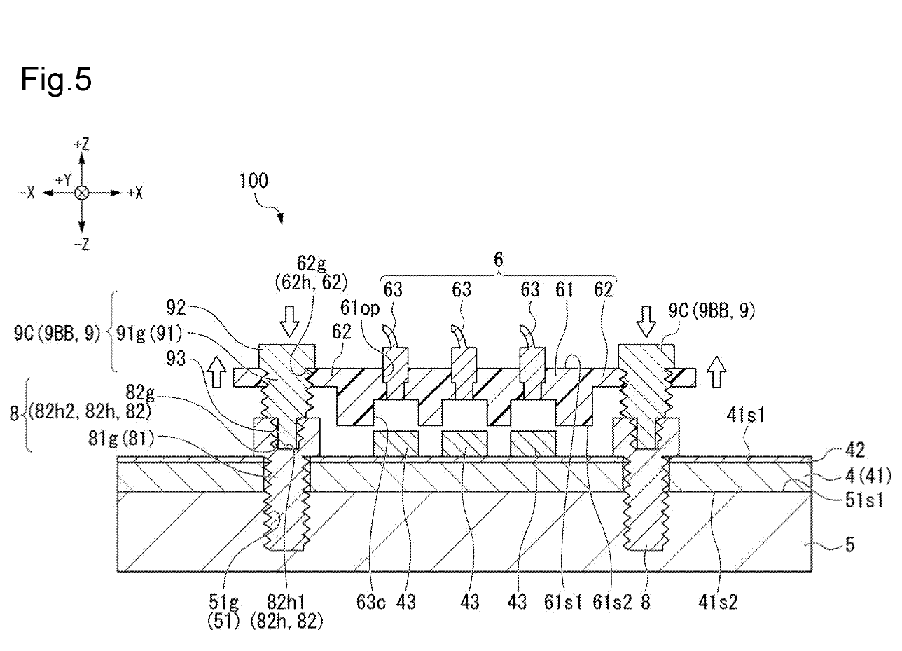

As illustrated in FIGS. 3 and 5, the first screw 8 includes a first shaft portion 81 having a third groove 81g engageable with a first groove 51g, and a first head portion 82.

The first screw 8 has the first head portion 82 in which the above first screw hole is formed.

The first screw 8 preferably contains a non-magnetic material containing, for example, copper (Cu) or aluminum (Al). More preferably, the first screw 8 may be constituted of a non-magnetic material. For example, the first screw 8 in the present disclosure is constituted of copper having a good heat transfer coefficient among non-magnetic materials. The first screw 8 containing copper facilitates cooling of the fixed board 4.

### Configuration of Second Screw

As illustrated in FIGS. 3 and 5, the second screw 9 includes a second shaft portion 91 having a fifth groove 91gs or a fifth groove 91g, and the second head portion 92. A root diameter of a screw portion in the fifth groove 91gs is smaller than a root diameter of a screw portion in the fifth groove 91g. The second screw 9 is an external thread.

A shape of the second head portion 92 is not limited. For example, the second screw 9 is a screw provided with a slot, a screw provided with a plus-shaped hole, a flange screw, a cap bolt, a hexagon head bolt, a wing bolt, or the like.

Here, the second screw 9 will be described in detail with reference to FIGS. 1 to 8B. There is a plurality of types of the second screw 9. In the present disclosure, examples of the second screw 9 include a first type second screw 9A, a second type second screw 9B, and the third type second screw 9C. The “first type second screw 9A” is an example of a second screw 9AA. The “second type second screw 9B” and the “third type second screw 9C” are examples of a second screw 9BB.

The second screw 9AA to which the “first type second screw 9A” belongs is engaged with the first screw hole (engagement hole 82h) to fix the connector unit 6. In the state illustrated in FIGS. 1 to 3, the second screw 9AA is used.

The second screw 9BB to which the “second type second screw 9B” and the “third type second screw 9C” belong is used in place of the second screw 9AA. In the state illustrated in FIGS. 4 and 5, the second screw 9BB is used. The second screw 9BB removes the second connector 63 fitted to the first connector 43. For example, in the present disclosure, the second screws 9BB simultaneously remove the second connectors 63 fitted to the plurality of first connectors 43 (see FIG. 5).

The second screw 9A has one of the following relationships. In either case, the second screw 9BB can be inserted into the second screw hole (engagement hole 62h) positioned in the extension direction (for example, the Z direction) of the first screw hole (engagement hole 82h). In the present example embodiment, the second screw 9A has a relationship related to (Case A).

(Case A): In a case where a root diameter of the “second screw hole” is larger than a root diameter of the “first screw hole”, the second screw 9A has the fifth groove 91gs engageable with the fourth groove 82g.

(Case B): In other cases, the second screw 9A has the fifth groove 91g engageable with the second groove 62g. For example, in a case where the root diameter of the “second screw hole” is equal to the root diameter of the “first screw hole”, the second screw 9A may have the fifth groove 91g engageable with the second groove 62g and the fourth groove 82g.

### First Type Second Screw 9A

The second screw 9A in the present disclosure has the fifth groove 91gs or the fifth groove 91g.

For example, in the present example embodiment, the second screw 9A has the fifth groove 91gs. In the second screw 9A, the second head portion 92 can press the connector unit 6. When the second screw 9A is fastened, the fifth groove 91gs and the fourth groove 82g are engaged with each other. Thereafter, in a state where the second head portion 92 presses the connector unit 6, the second screw 9A fixes the connector unit 6 to the first screw hole (see FIG. 3).

### Second Type Second Screw 9B

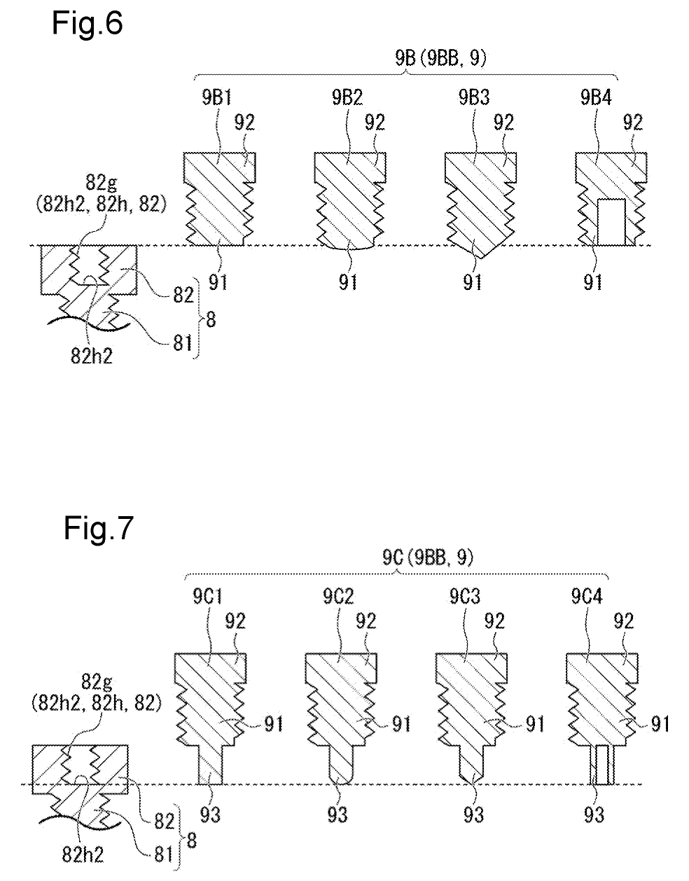

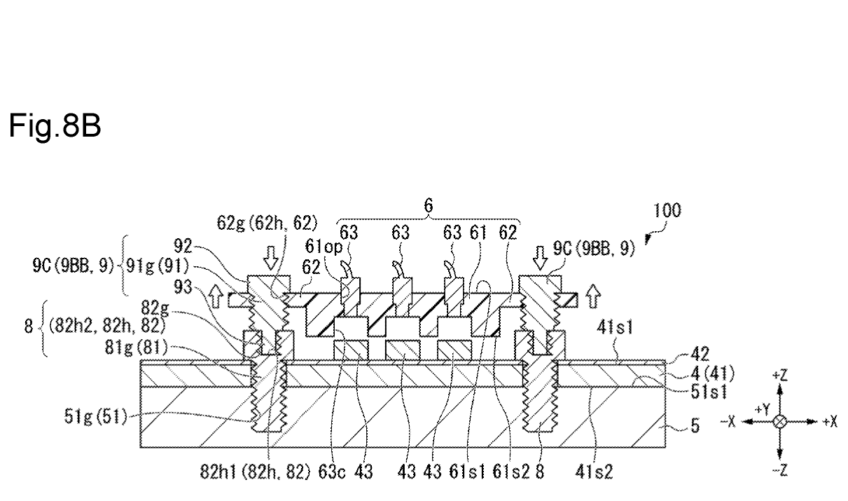

The second screw 9B in the present disclosure has the fifth groove 91g. In the second screw 9B, a distal end portion of the second shaft portion 91 (a screw tip of the second screw 9B) presses the first head portion 82. FIG. 6 illustrates an example of the screw tips of the second screws 9B (second screws 9B1, 9B2, 9B3, and 9B4). In the second screw 9B, the second shaft portion 91 is not engaged with the first screw hole (engagement hole 82h). When the fifth grooves 91g and the second grooves 62g of the engagement holes 62h are engaged with each other while the screw tips of the second screws 9B press the first head portions 82, the connector units 6 move in the +Z direction with the fastening of the second screws 9B. Thereafter, the second connectors 63 held by the main body 61 are simultaneously removed from the first connectors 43 (see FIG. 8A).

### Third Type Second Screw 9C

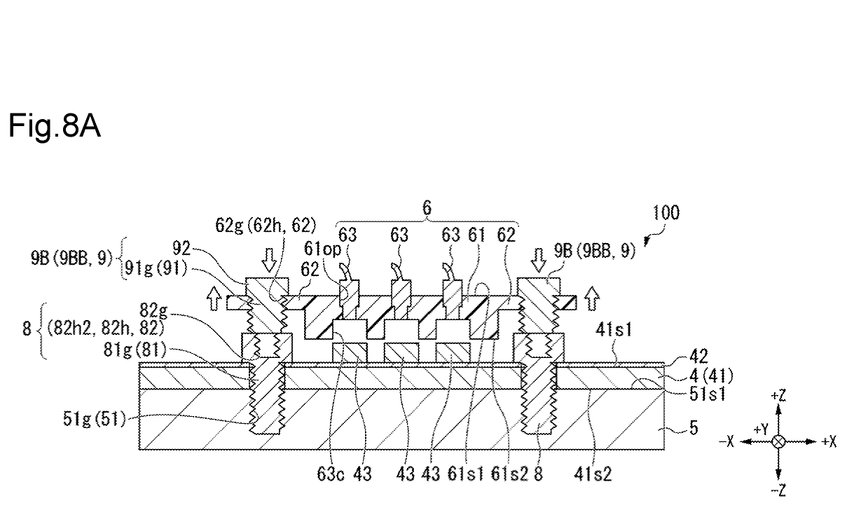

The second screw 9C in the present disclosure has the fifth groove 91g. The second screw 9C includes a third shaft portion 93 in the second screw 9A having the fifth groove 91g in (Case B). In the second screw 9C, a distal end portion of the third shaft portion 93 (a screw tip of the second screw 9C) presses the bottom surface 82h1. The third shaft portion 93 is continuously aligned with the second shaft portion 91 in a traveling direction of the second screw 9C. A diameter of the third shaft portion 93 is smaller than an outer diameter of the second shaft portion 91. FIG. 7 illustrates an example of the screw tips of the second screws 9C (second screws 9C1, 9C2, 9C3, and 9C4). In the second screw 9C, the third shaft portion 93 is not engaged with the first screw hole (engagement hole 82h). When the fifth grooves 91g and the second grooves 62g of the engagement holes 62h are engaged with each other while the screw tips of the second screws 9C press the bottom surfaces 82h1, the connector units 6 move in the +Z direction with the fastening of the second screws 9C. Thereafter, the second connectors 63 held by the main body 61 are simultaneously removed from the first connectors 43 (see FIG. 8B).

In the “third type second screw 9C”, since the diameter of the third shaft portion 93 is smaller than that of the second shaft portion 91, an area for pressing the bottom surface 82h1 tends to be small. As a result, even when the axis of the second groove 62g and the axis of the fourth groove 82g are slightly inclined, the bottom surface 82h1 is easily pressed by the third shaft portion 93.

### Method for Removing Connector Unit

A method for removing the connector unit in the present example embodiment will be described with reference to the drawings.

This method uses a chip (for example, the quantum chip 1) having a superconducting circuit, an interposer (for example, the interposer 2) on which the chip is mounted, a first screw (for example, the first screw 8) that fixes a board (for example, the board 4) electrically connected to the interposer and has a first head portion in which a first screw hole is formed, a connector unit (for example, the connector unit 6) that has a second screw hole and is fixable to the first screw hole, and a second screw (for example, the second screw 9) that includes a second shaft portion engageable with the second screw hole. The above second screw hole is positioned in an extension direction of the above first screw hole with respect to the above first screw hole.

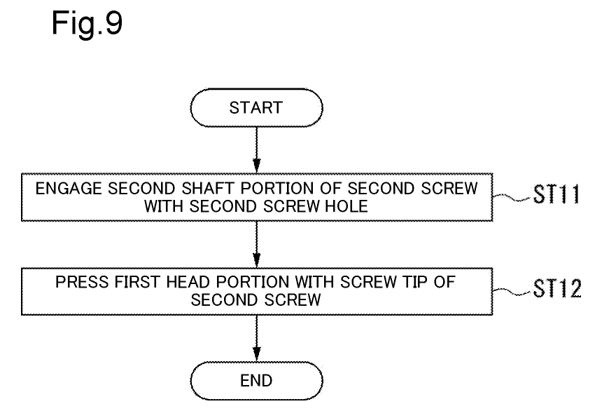

As illustrated in FIG. 9, first, an operator engages the second shaft portion of the second screw with the above second screw hole (step ST11: a step of engaging with the second screw hole).

Next, the operator presses the above first head portion with a screw tip of the second screw (step ST12: a step of pressing the first head portion).

Here, the connector unit is removed by selectively using the first screw hole and the second screw hole positioned in the extension direction of the screw holes. (Completed)

### Operation and Effect

According to the superconducting device of the present disclosure, the connector unit 6 has the second screw hole positioned in the extension direction of the first screw hole with respect to the first screw hole. As a result, the connector unit 6 is easily removed by selectively using the first screw hole and the second screw hole positioned in the extension direction of the screw holes.

Therefore, space saving of the superconducting device according to the present disclosure is easily achieved.

In the above disclosure, the superconducting device 100 has the structure in which second screw 9 is fitted in the extension direction of the screw hole. As a result, it is easy to minimize enlargement of a body of the superconducting device.

In the superconducting device 100 of the present disclosure, since “the connector unit 6 includes the plurality of connectors (for example, the second connectors 63), and the first holding unit (for example, the main body 61) that holds each connector”, an effect that “the plurality of connectors is simultaneously and easily removed” can also be obtained.

In the superconducting device 100 of the present disclosure, since “each connector is insertable into and removable from the above first holding unit”, an effect that “each connector is easily fitted and removed” can also be obtained.

In the superconducting device 100 of the present disclosure, since “the above first holding unit and the first screw 8 contain the non-magnetic material”, an effect that “electromagnetic noise is less likely to be applied to the superconducting circuit included in the chip (for example, the quantum chip 1)” can also be obtained.

In the superconducting device 100 of the present disclosure, by “further including the second screw 9 that includes the second shaft portion 91 engageable with the above second screw hole”, an effect that “the connector unit 6 is easily fitted or removed by selectively using the first screw hole and the second screw hole positioned in the extension direction of the screw holes” can also be obtained.

In the superconducting device 100 of the present disclosure, since “the second screw 9 (for example, the second screw 9A) further includes the second head portion 92, and the second head portion 92 is capable of pressing the connector unit 6”, an effect that “the connector unit 6 is easily fitted by selectively using the first screw hole and the second screw hole positioned in the extension direction of the screw holes” can also be obtained.

In the superconducting device 100 of the present disclosure, since “the screw tip of the second screw 9 (for example, the second screw 9B) presses the first head portion 82”, an effect that “the connector unit 6 is easily removed by selectively using the first screw hole and the second screw hole positioned in the extension direction of the screw holes” can also be obtained.

In the superconducting device 100 of the present disclosure, since “the second screw (for example, the second screw 9C) further includes the third shaft portion 93, the third shaft portion 93 is continuously aligned with the second shaft portion 91 in the traveling direction, and the diameter of the third shaft portion 93 is smaller than the outer diameter of the second shaft portion 91”, an effect that “the connector unit 6 is further easily removed by selectively using the first screw hole and the second screw hole positioned in the extension direction of the screw holes” can also be obtained.

In the superconducting device 100 of the present disclosure, since “the root diameter of the above second screw hole is larger than the root diameter of the first screw”, a lead of the screw engaged with the above second screw hole can be increased. Therefore, in the superconducting device 100 of the present disclosure, an effect that “the connector unit 6 is further easily removed by selectively using the first screw hole and the second screw hole positioned in the extension direction of the screw holes” can also be obtained.

In the superconducting device 100 of the present disclosure, since “the board 4 has the opening 41op, and the interposer 2 is housed in the opening 41op”, an effect that “enlargement of a body of the superconducting device is easily minimized” can also be obtained.

### First Modification

The bonding wires 3 are used to connect the interposer 2 and the board 4 in the above disclosure. The board 4 is provided with the opening 41op, and the interposer 2 is housed in the opening 41op. On the other hand, in the present modification, the interposer 2 and the board 4 may be connected by using a probe pin. In this case, the third wiring layer 42 is provided on the back surface 41s2. For example, the board 4 is arranged in the first direction (for example, in the Z direction) with respect to the interposer 2, and the probe pin is positioned between the interposer 2 and the board 4. The interposer 2 and the board 4 may be connected via the probe pin. At this time, the opening 41op may be closed in the board 4. At the time of the above connection by using the probe pin, the superconducting device 100 does not have to include the bonding wires 3.

The probe pin in the present modification can expand and contract in a longitudinal direction. For example, one end of the probe pin extends in the -Z direction, and the other end of the pin extends in the +Z direction. The probe pin includes a compression spring, and the one end or the other end of the probe pin is biased in the Z direction by the compression spring being elastically deformed in the Z direction. For example, since the biased probe pin is positioned between the interposer 2 and the board 4, stress is generated in the first wiring layer 22 and/or the third wiring layer 42. As a result, the probe pin is brought into close contact with the first wiring layer 22 and/or the third wiring layer 42.

### Second Modification

The recess 51r may be provided with a metal surface. The metal surface covers the recess 51r. The metal surface may be formed by including a metal surface containing gold (Au), platinum (Pt), palladium (Pd), or the like. The metal surface may be exposed toward the outside of the cooling unit 5, or may be exposed toward the outside of the cooling unit 5 after the metal surface is covered.

That is, the metal surface may be a thin film or may be layer-shaped. The metal surface is formed by means such as, for example, sputtering, vapor deposition, electroless plating, or electrolytic plating.

In this manner, the quantum chip 1 is surrounded by the metal surface and the first wiring layer 22 containing the material having the superconductivity, and a cavity resonator including the metal surface and the second wiring layer 23 is obtained. In this case, a gap is formed between the quantum chip 1 and the recess 51r. As the above gap of the cavity resonator is reduced, a resonance frequency of the cavity resonator shifts to a high frequency band. Since a resonance frequency generated in the quantum chip is about 5 GHz to 10 GHz, electromagnetic noise is less likely to be applied to the qubit circuit when the resonance frequency shifts to a frequency band higher than this frequency band (for example, 20 GHz to 30 GHz) by the reduction of the gap.

The superconducting material functions as magnetic shielding during cooling. Therefore, the quantum chip 1 surrounded by the metal surface and the second wiring layer 23 containing the alloy having the superconductivity is subjected to the magnetic shielding in addition to electromagnetic shielding. Therefore, as described above, electromagnetic noise is less likely to be applied to the qubit circuit.

A metal layer containing gold (Au), platinum (Pt), palladium (Pd), or the like may be formed on a front surface of the second wiring layer 23. For example, the metal layer containing gold (Au), platinum (Pt), palladium (Pd), or the like may be formed on the front surface of the second wiring layer 23 in a region outside the above cavity resonator.

When the metal surface is unnecessary, at least a part of the base material 11 may abut on the recess 51r. With such a configuration, the quantum chip 1 is directly cooled by the cooling unit 5, and operation of the quantum circuit included in the quantum chip 1 is easily stabilized.

### Third Modification

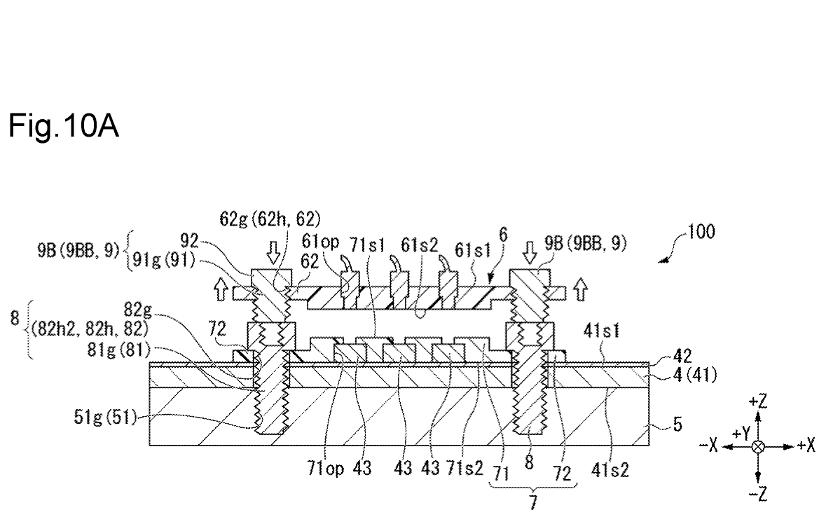

The superconducting device 100 may further include a protective member 7 (see FIG. 10A and FIG. 10B). The protective member 7 prevents an external force from being applied to the first connector 43 provided on the third wiring layer 42.

The protective member 7 includes a main body 71 and a pair of attachment portions 72.

The main body 71 can hold the first connector 43 on the board 4. The main body 71 is an example of a “second holding unit”.

The main body 71 has a front surface 71s1 and a back surface 71s2. The front surface 71s1 is a surface positioned on a side opposite to the back surface 71s2. The front surface 71s1 in the present example embodiment faces the +Z direction. The back surface 71s2 faces the first wiring layer 22. The back surface 71s2 in the present example embodiment faces the -Z direction. The back surface 61s2 of the main body 61 can be in contact with the front surface 71s1. The third wiring layer 42 can be in contact with the back surface 71s2. In the present modification, the protective member 7 is positioned between the third wiring layer 42 and the connector unit 6 in the Z direction.

A shape of the main body 71 is not particularly limited. For example, in the present example embodiment, the main body 71 extends along the horizontal direction. A cross section in the vertical direction of the main body 71 has a rectangular cross-sectional shape.

The main body 71 includes a plurality of openings 71op. Each opening 71op opens in the first direction (for example, the Z direction). The openings 71op are through holes. A part of an inner peripheral surface of the opening 71op is along an outer shape of the first connector 43. The first connector 43 is held at a predetermined position on the board 4 by the inner peripheral surface. At least a part of the second connector 63 is housed in the opening 71op.

The attachment portions 72 are provided at ends of the main body 71. One attachment portion 72 of the pair of attachment portions 72 extends from one end of the main body 71 along the horizontal direction. The other attachment portion 72 extends from the other end of the main body 71 along the horizontal direction. The attachment portion 72 has a bearing surface that supports the first screw 8. The first head portion 82 of the first screw 8 can come into contact with the bearing surface.

The attachment portion 72 has the bearing surface that supports the first screw 8. The bearing surface is provided with a through hole through which the first screw 8 can be inserted. As a result, the protective member 7 is fixed to the cooling unit 5 together with the board 4 by the first screw 8.

The main body 71 and the attachment portions 72 may contain the same material as that of the main body 61 or may contain a material different from that of the main body 61.

### Fourth Modification

A part of the main body 61 may have the second screw hole. In this case, the main body 61 may have an L shape, a U shape, or a square shape.

A part of the main body 71 may have an insertion hole. The insertion hole relates to the second screw hole provided in the main body 61. In this case, the main body 71 may have an L shape, a U shape, or a square shape.

### Second Example Embodiment

Hereinafter, one example embodiment according to the present disclosure will be described with reference to the drawings.

Hereinafter, an example of a configuration of a superconducting device in the present disclosure will be described with reference to the drawings.

### Configuration

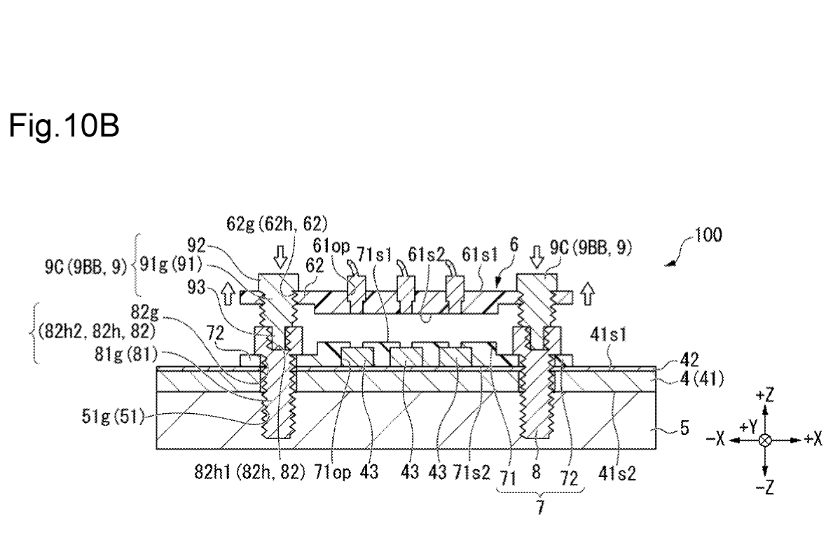

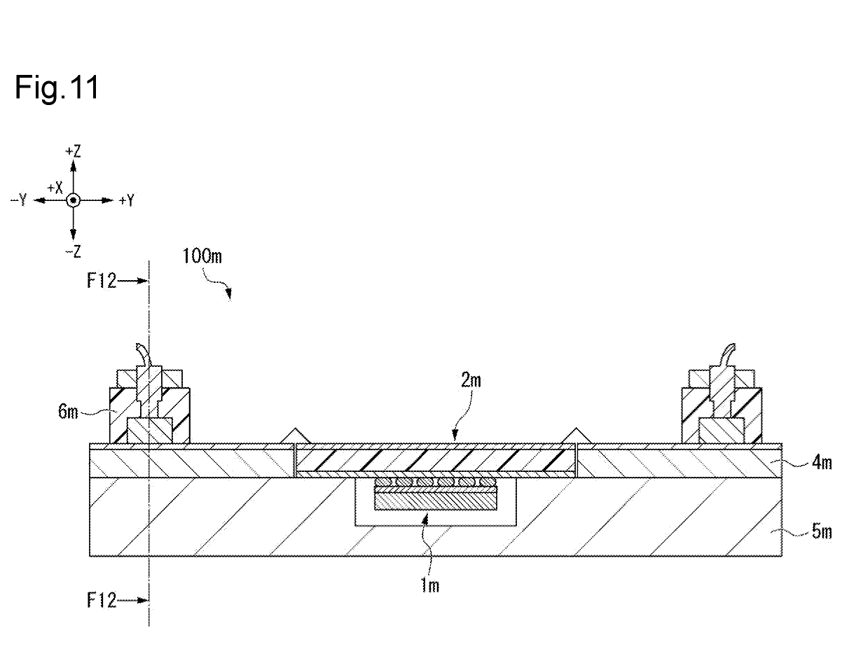

As illustrated in FIGS. 11 and 12, a superconducting device 100m includes a chip 1m that has a superconducting circuit, an interposer 2m on which the chip 1m is mounted, a board 4m electrically connected to the interposer 2m, a cooling unit 5m to which the board 4m is fixed, a first screw 8m that fixes the board 4m to the cooling unit 5m and has a first head portion 82m in which a first screw hole 82hm is formed, and a connector unit 6m fixable to the first screw hole 82hm, in which the connector unit 6m has a second screw hole 62hm positioned in an extension direction of the first screw hole 82hm with respect to the first screw hole 82hm.

### Operation and Effect

According to the superconducting device of the present disclosure, the connector unit 6m has the second screw hole 62hm positioned in the extension direction of the first screw hole 82hm with respect to the first screw hole 82hm. As a result, the connector unit 6m is easily removed by selectively using the first screw hole 82hm and the second screw hole 62hm positioned in the extension direction of the screw holes.

Therefore, space saving of the superconducting device according to the present disclosure is easily achieved.

### Third Example Embodiment

Hereinafter, one example embodiment according to the present disclosure will be described with reference to the drawings.

Hereinafter, an example of a method for removing a connector unit in the present disclosure will be described with reference to the drawing.

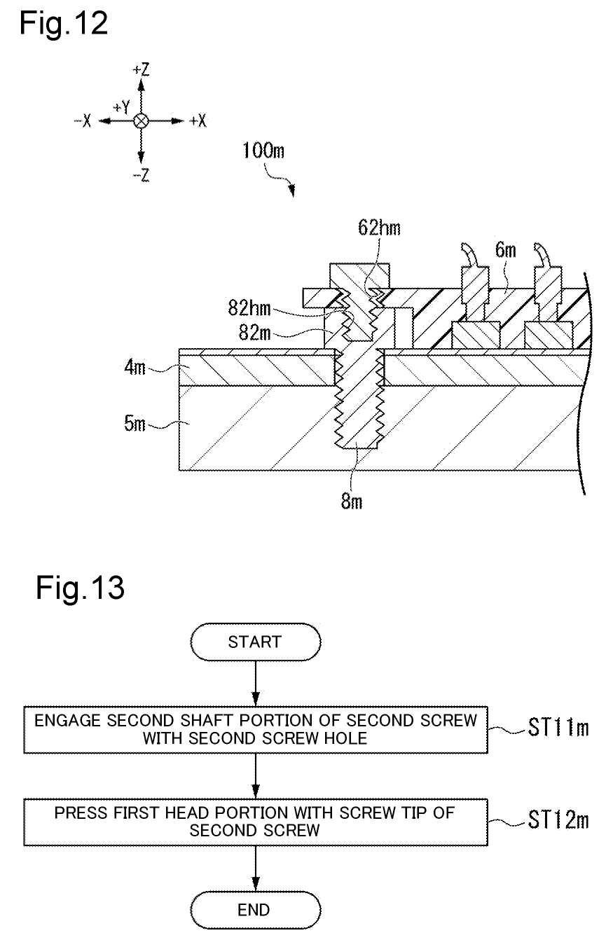

As illustrated in FIG. 13, the method for removing the connector unit uses a chip having a superconducting circuit, an interposer on which the chip is mounted, a first screw that fixes a board electrically connected to the interposer and has a first head portion in which a first screw hole is formed, the connector unit that has a second screw hole and is fixable to the first screw hole, and a second screw that includes a second shaft portion engageable with the second screw hole. The above second screw hole is positioned in an extension direction of the above first screw hole with respect to the above first screw hole.

The method for removing the connector unit includes a step of engaging the above second shaft portion with the above second screw hole (step ST11m: a step of engaging with the second screw hole), and a step of pressing the above first head portion with a screw tip of the above second screw (step ST12m: a step of pressing the first head portion).

### Operation and Effect

The connector unit used in the method for removing the connector unit of the present disclosure has the second screw hole positioned in the extension direction of the first screw hole with respect to the first screw hole. As a result, in the method for removing the connector unit of the present disclosure, the connector unit is easily removed by selectively using the above first screw hole and the above second screw hole positioned in the extension direction of the screw holes.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with other embodiments.

Some or all of the above example embodiments may also be described as the following Supplementary Notes, but are not limited to the following Supplementary Notes.

### Supplementary Note 1

A superconducting device including:

a chip that has a superconducting circuit;

an interposer on which the chip is mounted;

a board electrically connected to the interposer;

a cooling unit to which the board is fixed;

a first screw that fixes the board to the cooling unit and has a first head portion in which a first screw hole is formed; and

a connector unit fixable to the first screw hole,

the connector unit having a second screw hole positioned in an extension direction of the first screw hole with respect to the first screw hole.

### Supplementary Note 2

The superconducting device according to Supplementary Note 1, in which

the connector unit includes a plurality of connectors, and a first holding unit that holds each connector.

### Supplementary Note 3

The superconducting device according to Supplementary Note 2, in which

each connector is insertable into and removable from the first holding unit.

### Supplementary Note 4

The superconducting device according to Supplementary Note 2, in which

the first holding unit and the first screw contain a non-magnetic material.

### Supplementary Note 5

The superconducting device according to any one of Supplementary Notes 1 to 4, further including

a second holding unit that holds, on the board, a connection unit electrically connectable to the connector unit,

in which the second holding unit is fixed to the cooling unit together with the board.

### Supplementary Note 6

The superconducting device according to any one of Supplementary Notes 1 to 5, further including

a second screw that includes a second shaft portion engageable with the second screw hole.

### Supplementary Note 7

The superconducting device according to Supplementary Note 6, in which

the second screw further includes a second head portion, and

the second head portion is capable of pressing the connector unit.

### Supplementary Note 8

The superconducting device according to Supplementary Note 6, in which

a screw tip of the second screw presses the first head portion.

### Supplementary Note 9

The superconducting device according to Supplementary Note 8, in which

the second screw further includes a third shaft portion,

the third shaft portion is continuously aligned with the second shaft portion in a traveling direction, and

a diameter of the third shaft portion is smaller than an outer diameter of the second shaft portion.

### Supplementary Note 10

The superconducting device according to any one of Supplementary Notes 1 to 9, in which

a root diameter of the second screw hole is larger than a root diameter of the first screw.

### Supplementary Note 11

The superconducting device according to any one of Supplementary Notes 1 to 10, in which

the board has an opening, and

the interposer is housed in the opening.

### Supplementary Note 12

A method for removing a connector unit, the method including, by using

a chip that has a superconducting circuit,

an interposer on which the chip is mounted,

a first screw that fixes a board electrically connected to the interposer and has a first head portion in which a first screw hole is formed,

a connector unit that has a second screw hole and is fixable to the first screw hole, and

a second screw that includes a second shaft portion engageable with the second screw hole,

a step of engaging the second shaft portion with the second screw hole; and

a step of pressing the first head portion with a screw tip of the second screw,

the second screw hole being positioned in an extension direction of the first screw hole with respect to the first screw hole.

### Supplementary Note 13

The method for removing the connector unit according to Supplementary Note 12, in which

the connector unit includes a plurality of connectors, and a first holding unit that holds each connector.

### Supplementary Note 14

The method for removing the connector unit according to Supplementary Note 13, in which

each connector is insertable into and removable from the first holding unit.

### Supplementary Note 15

The method for removing the connector unit according to Supplementary Note 13, in which

the first holding unit and the first screw contain a non-magnetic material.

### Supplementary Note 16

The method for removing the connector unit according to any one of Supplementary Notes 12 to 15, further including:

a cooling unit to which the board is fixed; and

a second holding unit that holds, on the board, a connection unit electrically connectable to the connector unit,

in which the second holding unit is fixed to the cooling unit together with the board.

### Supplementary Note 17

The method for removing the connector unit according to any one of Supplementary Notes 12 to 16, further including

a second screw that includes a second shaft portion engageable with the second screw hole.

### Supplementary Note 18

The method for removing the connector unit according to Supplementary Note 17, in which

the second screw further includes a second head portion, and

the second head portion is capable of pressing the connector unit.

### Supplementary Note 19

The method for removing the connector unit according to Supplementary Note 17, in which

a screw tip of the second screw presses the first head portion.

### Supplementary Note 20

The method for removing the connector unit according to Supplementary Note 19, in which

the second screw further includes a third shaft portion,

the third shaft portion is continuously aligned with the second shaft portion in a traveling direction, and

a diameter of the third shaft portion is smaller than an outer diameter of the second shaft portion.

### Supplementary Note 21

The method for removing the connector unit according to any one of Supplementary Notes 12 to 20, in which

a root diameter of the second screw hole is larger than a root diameter of the first screw.

### Supplementary Note 22

The method for removing the connector unit according to any one of Supplementary Notes 12 to 21, in which

the board has an opening, and

the interposer is housed in the opening.

1. A superconducting device comprising:
a chip that has a superconducting circuit;
an interposer on which the chip is mounted;
a board electrically connected to the interposer;
a cooling unit to which the board is fixed;
a first screw that fixes the board to the cooling unit and has a first head portion in which a first screw hole is formed; and
a connector unit fixable to the first screw hole,
the connector unit having a second screw hole positioned in an extension direction of the first screw hole with respect to the first screw hole.

2. The superconducting device according to claim 1, wherein
the connector unit includes a plurality of connectors, and
a first holding unit that holds each connector.

3. The superconducting device according to claim 2, wherein
each connector is insertable into and removable from the first holding unit.

4. The superconducting device according to claim 2, wherein
the first holding unit and the first screw contain a non-magnetic material.

5. The superconducting device according to claim 1, further comprising
a second holding unit that holds, on the board, a connection unit electrically connectable to the connector unit, wherein
the second holding unit is fixed to the cooling unit together with the board.

6. The superconducting device according to claim 1, further comprising
a second screw that includes a second shaft portion engageable with the second screw hole.

7. The superconducting device according to claim 6, wherein
the second screw further includes a second head portion, and
the second head portion is capable of pressing the connector unit.

8. The superconducting device according to claim 6, wherein
a screw tip of the second screw presses the first head portion.

9. The superconducting device according to claim 8, wherein
the second screw further includes a third shaft portion,
the third shaft portion is continuously aligned with the second shaft portion in a traveling direction, and
a diameter of the third shaft portion is smaller than an outer diameter of the second shaft portion.

10. A method for removing a connector unit in a superconducting device comprising an interposer on which a chip having a superconducting circuit is mounted, a first screw that fixes a board electrically connected to the interposer to a cooling unit and has a first head portion in which a first screw hole is formed, a connector unit fixable to the first screw hole and having a second screw hole positioned in an extension direction of the first screw hole, and a second screw including a second shaft portion engageable with the second screw hole, the method comprising:
engaging the second shaft portion with the second screw hole; and
pressing the first head portion with a screw tip of the second screw.
